(19) United States
(12) Patent Application Publication
(10) Pub. No.: US 2024/0128387 A1
(43) Pub. Date: Apr. 18, 2024

(54) SYSTEMS AND METHODS TO CONVERT SOLAR RADIATION INTO ELECTRICITY

(71) Applicant: Nate DeVault, Denver, CO (US)

(72) Inventor: Nate DeVault, Denver, CO (US)

(21) Appl. No.: 18/489,819

(22) Filed: Oct. 18, 2023

Related U.S. Application Data
(60) Provisional application No. 63/417,167, filed on Oct. 18, 2022.

(51) Int. Cl. H01L 31/0475; H01L 31/05; H01L 31/052; H01L 31/054

(52) U.S. Cl. CPC H01L 31/0475; H01L 31/0504; H01L 31/052; H01L 31/0547

(57) ABSTRACT

Various aspects of this disclosure relate to the improved performance of passive arrays of photovoltaic cells that comprise three-dimensional configurations that allow the photovoltaic cells to capture sunlight that is reflected off of other photovoltaic cells. Historical arrays generally optimized the orientations of photovoltaic cells to capture direct sunlight. This disclosure demonstrates that optimizing the orientation of photovoltaic cells to instead capture sunlight reflected by other photovoltaic cells results in significant improvements over historical arrays.

### CROSS-REFERENCE TO RELATED PATENT APPLICATIONS

This patent application claims priority to U.S. Provisional Patent Application No. 63/417,167, filed Oct. 18, 2022, which is incorporated by reference in its entirety.

### BACKGROUND

Solar power currently generates about five percent of global energy, and utility-scale solar photovoltaic power in favorable geographies is now cost competitive with nearly every other energy source. The development of improved batteries to store electricity generated by solar power, environmental and geopolitical pressures associated with fossil fuels, and drawbacks of competing renewable energy sources favor broader adoption of solar power.

Much of solar power innovation focuses on improving the efficiency, reducing the cost, and increasing the lifespan of photovoltaic cells. Other innovation relates to the implementation and storage of solar power strategies at scale. Additional strategies to improve the production of electricity from solar energy are desirable.

### SUMMARY

Various aspects of this disclosure relate to improvements to the configuration of arrays of photovoltaic cells based on insights gleamed from nature. Evergreen coniferous trees collect sunlight using long, thin needles. Unlike most deciduous trees, many evergreen coniferous trees have needles capable of absorbing light from any angle. In many instances, needles project radially from branches rather than orienting themselves in relation to sunlight. The effect of such orientation on efficiency of photosynthesis remains poorly characterized.

This disclosure describes the orientation of photovoltaic cells in three-dimensional patterns that borrow from and expand upon the geometries of coniferous tree needles found in nature. Specifically, the orientation of photovoltaic cells in convex patterns allows the reflection of sunlight that is not converted into electricity by a photovoltaic cell to be reflected onto one or more other photovoltaic cells for conversion into electricity. Surprisingly, the efficiency of light capture improved per unit surface area of the photovoltaic cells for arrays oriented in convex patterns relative to planar configurations, which was unexpected because orientating photovoltaic cells such that they reflect light onto other photovoltaic cells requires orientation of the photovoltaic cells away from the sunlight.

This efficiency improvement can be explained by the improved conversion of sunlight into electricity at a greater range of angles relative to planar surfaces, which improves the collection of sunlight over the course of a day. Passive arrays that lack automation to orient photovoltaic cells in relation to sunlight therefore display greater efficiency when they optimize the absorption of both direct sunlight and sunlight that photovoltaic cells of a passive array reflect onto other photovoltaic cells of the passive array.

### BRIEF DESCRIPTION OF THE DRAWINGS

FIGS. 1A and 1B include a drawing of a top view (FIG. 1A) and a side view (FIG. 1B) of an array of photovoltaic cells arranged on two convex surfaces.

FIG. 2 is a drawing of a side view of an array of photovoltaic cells arranged on three convex surfaces.

FIG. 3 includes a drawing of convex aluminum sheeting upon which a portion of an array of photovoltaic cells can be mounted as well as a barbed fastener.

FIGS. 4A and 4B includes a drawing of a top view (FIG. 4A) of convex aluminum sheeting and an array of photovoltaic cells (FIG. 4B) to be mounted on the convex aluminum sheeting.

FIG. 5 is a drawing of convex aluminum sheeting upon which an array of photovoltaic cells has been mounted.

FIG. 6 is a drawing of a top view of an array of photovoltaic cells mounted on aluminum sheeting with a parquet style orientation.

FIG. 7 is a drawing of a solar panel array in which an array of photovoltaic cells is mounted on convex aluminum sheeting.

FIG. 8 is a circuit diagram that depicts solar power arrays comprising photovoltaic cells wired in series and in parallel.

FIG. 9 is a circuit diagram of a portion of an array of photovoltaic cells wired both in series and in parallel.

FIG. 10 depicts an array of photovoltaic cells mounted on aluminum sheeting with a parquet style orientation and also depicts wiring that connects the photovoltaic cells.

FIG. 11 depicts an array of photovoltaic cells mounted on aluminum sheeting with a parquet style orientation with a cover to protect debris from accumulating between rails of the array.

FIGS. 12A and 12B are drawings of a convex polyhedron from a perspective view (FIG. 12A) and a top view (FIG. 12B).

FIGS. 13A and 13B are drawings of a convex polyhedron from a perspective view (FIG. 13A) and a top view (FIG. 13B).

FIG. 14 is a drawing of an array of convex polyhedral from a top view.

FIG. 15 is a drawing of an array of convex polyhedral from a perspective view.

FIG. 16 is a flowchart that depicts the conversion of sunlight and reflected sunlight into electricity according to various embodiments of this disclosure.

FIG. 17 is a photograph of a rail array (left) and flat array (right) as described in Example 2.

FIG. 18 is a histogram that depicts the current generated by the rail array and the flat array of FIG. 17 at different half-hour timepoints throughout a day.

### DETAILED DESCRIPTION

In the following description, for the purposes of explanation, numerous specific details are set forth in order to provide a thorough understanding of the present invention. It will be apparent, however, to one skilled in the art that the present invention may be practiced without some of these specific details. For example, while various features are ascribed to particular implementations, it should be appreciated that the features described with respect to one implementation may be incorporated with some other implementations as well. Similarly, however, no single feature or features of any described implementation should be considered essential to the invention as some implementations of the invention may omit such features.

Various aspects of this disclosure relate to a solar panel array, comprising an array of photovoltaic cells. In some embodiments, the array of photovoltaic cells consists of at least two photovoltaic cells that are in electrical communication such that each photovoltaic cell of the array of photovoltaic cells is configured to transmit electrical power to the same electrical circuit.

The term “photovoltaic cell” refers to a material that is capable of absorbing photons to excite electrons to generate electrical current, examples of which include various semiconducting materials such as doped silicon. Many photovoltaic cells are known, and the nature of the photovoltaic cells used in the various embodiments of this disclosure is not limiting.

The term “comprising” refers to an open set, for example, such that a solar panel array that comprises an array of photovoltaic cells can also comprise an electrical circuit.

In some embodiments, each photovoltaic cell of the array of photovoltaic cells is configured to receive one or both of direct sunlight and reflected light. In some specific embodiments, the direct sunlight consists of photons emitted from the sun. In some very specific embodiments, the sunlight is “direct” sunlight because the sunlight consists of photons emitted from the sun, which photons lack any interaction with man-made optics prior to any receiving of the sunlight by a photovoltaic cell of this disclosure.

The term “sunlight” may be replaced with the more general term “light” in any embodiments of this disclosure. The inventor nevertheless contemplates that most commercial embodiments of this disclosure will utilize light that is sunlight.

In some embodiments, each photovoltaic cell that is configured to receive the direct sunlight is configured to convert a first portion of the direct sunlight into electricity. In some specific embodiments, each photovoltaic cell that is configured to receive the direct sunlight is configured to convert a first portion of the direct sunlight into electrical current. In some very specific embodiments, each photovoltaic cell that is configured to receive the direct sunlight is configured to convert a first portion of the direct sunlight into direct current electricity.

In some embodiments, at least some photovoltaic cells that are configured to receive the direct sunlight are configured to reflect a second portion of the direct sunlight to one or more other photovoltaic cells that are configured to receive reflected light. In some specific embodiments, the at least some photovoltaic cells that are configured to receive the direct sunlight are configured to reflect the second portion of the direct sunlight to one or more other photovoltaic cells that are configured to receive reflected light and that are optionally also configured to receive the direct sunlight, depending on an orientation of the solar panel array relative to the sun. In some very specific embodiments, the at least some photovoltaic cells that are configured to receive the direct sunlight are configured to reflect the second portion of the direct sunlight to one or more other photovoltaic cells that are configured to receive reflected light and that are optionally also configured to receive the direct sunlight such that one or more photovoltaic cells may be configured to receive direct sunlight, reflect a portion of direct sunlight, and/or receive a different portion of reflected sunlight, for example, depending on the orientation of the solar panel array relative to the sun.

In some embodiments, the first portion of the direct sunlight and the second portion of the direct sunlight have an angle of incidence, which is the same for any given photovoltaic cell that is configured to both receive and reflect direct sunlight.

In some embodiments, the angle of incidence of the first portion of the direct sunlight and the second portion of the direct sunlight is the same for any given photovoltaic cell that is configured to receive the direct sunlight.

In some embodiments, each photovoltaic cell that is configured to receive reflected light is configured to convert a first reflected portion of the reflected light into electricity.

In some embodiments, at least some photovoltaic cells that are configured to receive reflected light are optionally configured to reflect a second reflected portion of the reflected light to one or more other photovoltaic cells that are configured to receive reflected light. In some specific embodiments, at least some photovoltaic cells that are configured to receive reflected light are configured to reflect a second reflected portion of the reflected light to one or more other photovoltaic cells that are configured to receive reflected light.

In some embodiments, the solar panel array optionally comprises one or more photovoltaic cells that are configured to receive the direct sunlight and convert a portion of the direct sunlight into electricity, but that are not configured to reflect a different portion of the direct sunlight to one or more other photovoltaic cells, which configuring optionally depends upon an array orientation of the solar panel array relative to the sun or a cell orientation of the one or more photovoltaic cells relative to the sun.

In some embodiments, the array of photovoltaic cells converts at least 70 percent and no greater than 98 percent of the direct sunlight into electricity and reflects at least 2 percent and no greater than 30 percent of the direct sunlight.

In some embodiments, at least 9 percent and no greater than 29 percent of the direct sunlight is both reflected and converted into electricity.

In some embodiments, conversion of the reflected light into electricity generates at least 1 kilowatt-hour of electricity per every 10 kilowatt-hours of electricity that conversion of the direct sunlight into electricity generates. In some specific embodiments, conversion of the reflected light into electricity generates at least 4 kilowatt-hours of electricity per every 10 kilowatt-hours of electricity that conversion of the direct sunlight into electricity generates. In some very specific embodiments, conversion of the reflected light into electricity generates at least 8 kilowatt-hours of electricity per every 10 kilowatt-hours of electricity that conversion of the direct sunlight into electricity generates.

The phrase “conversion of the reflected light into electricity generates at least 1 kilowatt-hour of electricity per every 10 kilowatt-hours of electricity that conversion of the direct sunlight into electricity generates” and similar phrases refer to relative amounts of electricity and do not require, for example, the generation of 10 kilowatt-hours of electricity from direct sunlight as long as at least 1 kilowatt-hour of electricity would be generated from reflected light if 10 kilowatt-hours of electricity were generated from direct sunlight; an infringing solar panel array might fall within the scope of this feature, for example, by generating 1 watt-hour of electricity from reflected light for every 10 watt-hours of electricity that is generated from direct sunlight.

In some embodiments, the solar panel array comprises an electrical circuit that is configured to transmit electrical power from the array of photovoltaic cells.

In some embodiments, the electrical circuit comprises each photovoltaic cell of the array of photovoltaic cells.

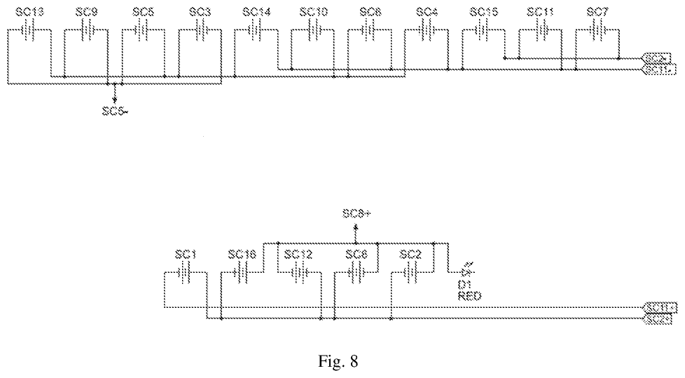

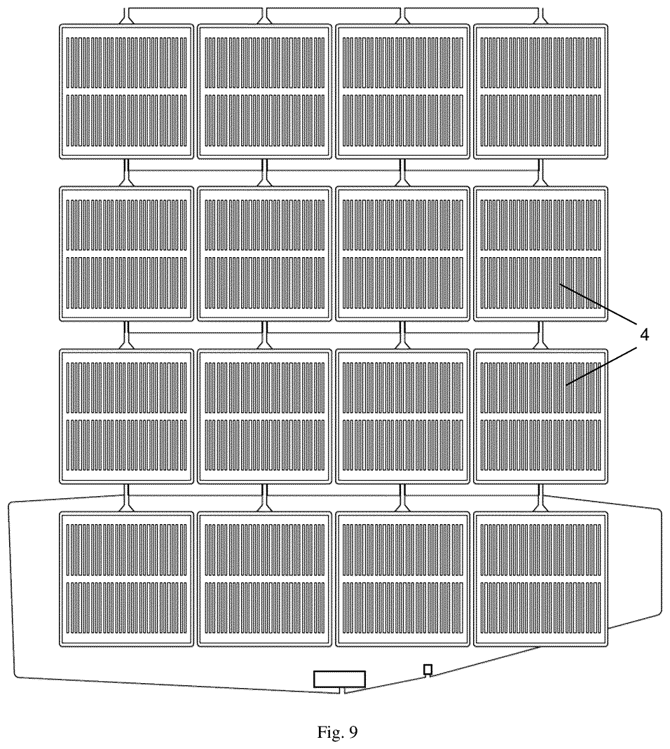

In some embodiments, each photovoltaic cell of the array of photovoltaic cells is connected within the electrical circuit both in series and in parallel such that the electrical circuit can transmit electrical power when less than all of the photovoltaic cells of the array of photovoltaic cells are converting light into electricity. FIGS. 8 and 9 depict the connection of photovoltaic cells within an electrical circuit both in series and in parallel.

In some embodiments, the solar panel array comprises one or more heat sinks in thermal communication each photovoltaic cell of the array of photovoltaic cells, wherein the one or more heat sinks comprise aluminum; and the aluminum has sufficient surface area in thermal communication with a fluid such that the one or more heat sinks are capable of cooling the array of photovoltaic cells by at least 10 degrees Celsius following 3 hours of exposure of the solar panel array to direct sunlight.

In some embodiments, the array of photovoltaic cells has a temperature that is greater than 25 degrees Celsius following the 3 hours of exposure of the solar panel array to direct sunlight; a reference solar panel array that comprises a reference array of photovoltaic cells lacks the one or more heat sinks and is otherwise identical to the solar panel array; and the reference array of photovoltaic cells has a reference temperature that is at least 10 degrees Celsius greater than the temperature of the array of photovoltaic cells following the 3 hours of exposure of the solar panel array to direct sunlight

In some embodiments, cooling the array of photovoltaic cells increases the conversion of light into electricity by about 0.45 percent to about 0.50 percent per degree Celsius relative to a reference, uncooled array of photovoltaic cells. In some specific embodiments, cooling the array of photovoltaic cells increases the conversion of light into electricity by at least 5 percent relative to a reference, uncooled array of photovoltaic cells.

In some embodiments, the heat sink has a heat absorption efficiency of at least 10 percent. In some specific embodiments, the heat sink has a heat absorption efficiency of at least 10 percent. In some very specific embodiments, the heat sink has a heat absorption efficiency of at least 40 percent and no greater than 70 percent.

In some embodiments, the heat sink increases the efficiency of the solar panel array by at least 1 percent. In some specific embodiments, the heat sink increases the efficiency of the solar panel array by at least 5 percent. In some very specific embodiments, the heat sink increases the efficiency of the solar panel array by at least 10 percent.

The embodiments of this disclosure generate additional electricity, which correlates with additional heat, and heat sinks allow for dissipation of the additional heat and improved performance of the solar panel arrays.

In some embodiments, the solar panel array comprises a three-dimensional shape that comprises at least two convex surfaces.

In some embodiments, each photovoltaic cell of the array of photovoltaic cells resides on a convex surface of the at least two convex surfaces.

In some embodiments, each photovoltaic cell that is configured to receive reflected light is a receiving photovoltaic cell that resides on a different convex surface relative to each photovoltaic cell that reflects light that the receiving photovoltaic cell receives.

In some embodiments, when a receiving photovoltaic cell receives reflected light from more than one other photovoltaic cell, then the amount of reflected light that the receiving photovoltaic cell receives from each other photovoltaic cell correlates with distance between the receiving photovoltaic cell and each other photovoltaic cell.

In some embodiments, the photovoltaic cells of the array of photovoltaic cells have a combined total surface area that is capable of receiving light; a reference array of photovoltaic cells comprises reference photovoltaic cells that have a reference combined total surface area that is capable of receiving light; and the reference total surface area is equal to the combined total surface area.

In some embodiments, the array of photovoltaic cells is a passive array that lacks any automated means to orient any photovoltaic cell in relation to sunlight.

In some embodiments, the reference photovoltaic cells of the reference array of photovoltaic cells are arranged in a plane such that each reference photovoltaic cell is oriented in the same direction, no reference photovoltaic cell is capable of reflecting any portion of light to any other reference photovoltaic cell, and the reference array of photovoltaic cells is otherwise identical to the array of photovoltaic cells.

In some embodiments, the photovoltaic cells of the array of photovoltaic cells convert light into electricity at a rate in kilowatt-hours of electricity per 10 megajoules of light when the array of photovoltaic cells is optimally oriented in relation to the sunlight, but passively oriented in that the array of photovoltaic cells does not reorient in relation to the sunlight over a period of time; the reference photovoltaic cells of the reference array of photovoltaic cells convert light into electricity at a reference rate in kilowatt-hours of electricity per 10 megajoules of light when the reference array of photovoltaic cells is optimally oriented in relation to the sunlight, but passively oriented in that the reference array of photovoltaic cells does not reorient in relation to the sunlight over a period of time; and the array of photovoltaic cells displays better efficiency than the reference array of photovoltaic cells such that the rate of conversion of light into electricity over a time period of a full day is at least 10 percent greater than the reference rate of conversion of light into electricity over the time period of the full day. In some specific embodiments, the array of photovoltaic cells displays better efficiency than the reference array of photovoltaic cells such that the rate of conversion of light into electricity over a time period of a full day is at least 40 percent greater than the reference rate of conversion of light into electricity over the time period of the full day. In some very specific embodiments, the array of photovoltaic cells displays better efficiency than the reference array of photovoltaic cells such that the rate of conversion of light into electricity over a time period of a full day is at least 80 percent greater than the reference rate of conversion of light into electricity over the time period of the full day.

In some embodiments, the first portion of direct sunlight and the first reflected portion of the reflected light each have a range of wavelengths; and the range of wavelengths of the first portion of direct sunlight overlaps with the range of wavelengths of the first reflected portion of the reflected light.

The term “overlaps” as set forth in “the range of wavelengths of the first portion of direct sunlight overlaps with the range of wavelengths of the first reflected portion of the reflected light” means that similar wavelengths of sunlight are converted into electricity regardless of whether the sunlight is direct sunlight or reflected sunlight. A solar array might alternatively be designed, for example, such that a first photovoltaic cell receives direct sunlight, selectively converts certain wavelengths into electricity, and reflects other wavelengths to a second photovoltaic cell that selectively converts the other wavelengths into electricity, i.e., the first and second photovoltaic cells preferentially convert different wavelengths into electricity. One of the advantages of this disclosure is that the same type of photovoltaic cells may be used in an array; the photovoltaic cells reflect sunlight due to inefficiency at converting optimal wavelengths into electricity, and photovoltaic cells that convert reflected sunlight into electricity exploit this inefficiency to improve upon the inefficiencies of conventional solar arrays. The wavelengths of the direct sunlight that are converted into electricity therefore overlap the wavelengths of the reflected light that are converted into electricity in various embodiments of this disclosure.

In some embodiments, the solar panel array is a passive solar panel array that lacks any integration of an automated means to orient any photovoltaic cell in relation to sunlight.

In some embodiments, the solar panel array comprises a primary photovoltaic cell and a secondary photovoltaic cell.

In some embodiments, the primary photovoltaic cell is configured to simultaneously convert a first portion of light into electricity and reflect a second portion of light.

In some embodiments, the first portion of light and the second portion light consist of sunlight that has an identical angle of incidence relative to the primary photovoltaic cell.

In some embodiments, the solar panel array is configured such that the second portion of light is reflected from the primary photovoltaic cell to the secondary photovoltaic cell.

In some embodiments, the secondary photovoltaic cell is configured to receive the second portion of light and convert the second portion of light into electricity.

In some embodiments, the secondary photovoltaic cell is optionally configured to receive direct sunlight, to convert a portion of the direct sunlight into electricity, and to reflect another portion of the sunlight.

In some embodiments, the second portion of light generates at least 10 kilowatt-hours of electricity per every 1000 kilowatt-hours of electricity that the first portion of light generates. In some specific embodiments, the second portion of light generates at least 100 kilowatt-hours of electricity per every 1000 kilowatt-hours of electricity that the first portion of light generates. In some very specific embodiments, the second portion of light generates at least 200 kilowatt-hours of electricity per every 1000 kilowatt-hours of electricity that the first portion of light generates.

In some embodiments, the primary photovoltaic cell is configured to refract photons.

In some embodiments, the second portion of light comprises refracted and reflected photons that are both refracted and reflected by the primary photovoltaic cell.

In some embodiments, the second portion of light optionally comprises reflected photons that are reflected but not refracted by the primary photovoltaic cell.

In some embodiments, the second portion of light comprises more refracted and reflected photons than reflected photons.

In some embodiments, the solar panel array comprises a third photovoltaic cell.

In some embodiments, the primary photovoltaic cell is configured to simultaneously convert the first portion of light into electricity, reflect the second portion of light, and refract a third portion of light.

In some embodiments, the third photovoltaic cell is configured to receive the third portion of light and convert the third portion of light into electricity.

In some embodiments, the first portion of light, the second portion light, and the third portion of light consist of sunlight that has an identical angle of incidence relative to the primary photovoltaic cell.

In some embodiments, the third portion of light generates at least 1 kilowatt-hour of electricity per every 1000 kilowatt-hours of electricity that the first portion of light generates. In some specific embodiments, the third portion of light generates at least 10 kilowatt-hours of electricity per every 1000 kilowatt-hours of electricity that the first portion of light generates. In some very specific embodiments, the third portion of light generates at least 100 kilowatt-hours of electricity per every 1000 kilowatt-hours of electricity that the first portion of light generates.

Various aspects of this disclosure relate to a method of generating solar power.

In some embodiments, the method comprises providing a solar panel array that comprises an array of photovoltaic cells that comprise photovoltaic cells that are configured to receive one or both of direct sunlight and reflected light.

In some embodiments, the method comprises exposing the solar panel array to direct sunlight such that: (a) at least some photovoltaic cells receive the direct sunlight and convert a first portion of the direct sunlight into electricity; (b) at least some photovoltaic cells that receive the direct sunlight reflect a second portion of the direct sunlight to one or more other photovoltaic cells that are configured to receive reflected light; (c) at least some photovoltaic cells receive the reflected light and convert a first reflected portion of the reflected light into electricity; and (d) at least some photovoltaic cells that receive the reflected light optionally reflect a second reflected portion of the reflected light to one or more other photovoltaic cells that are configured to receive reflected light.

In some embodiments, the method is performed such that steps (c) and (d) are optionally repeated one or more times.

In some embodiments, the first portion of the direct sunlight and the second portion of the direct sunlight have an angle of incidence, which is the same for any given photovoltaic cell that is configured to both receive and reflect direct sunlight as set forth in steps (a) and (b).

In some embodiments, conversion of reflected light into electricity during step (c) generates at least 1 kilowatt-hour of electricity per every 100 kilowatt-hours of electricity that conversion of the direct sunlight into electricity during step (a) generates. In some specific embodiments, conversion of reflected light into electricity during step (c) generates at least 1 kilowatt-hour of electricity per every 10 kilowatt-hours of electricity that conversion of the direct sunlight into electricity during step (a) generates. In some very specific embodiments, conversion of reflected light into electricity during step (c) generates at least 1 kilowatt-hour of electricity per every 5 kilowatt-hours of electricity that conversion of the direct sunlight into electricity during step (a) generates.

In some embodiments, the solar power array is a solar power array as described anywhere in this disclosure.

In some embodiments, exposing the solar panel array to direct sunlight comprises orienting the solar panel array such that at least one of the photovoltaic cells of the solar panel array does not convert light into electricity; the solar panel array comprises an electrical circuit that is configured to transmit electrical power from the array of photovoltaic cells; the method comprises transmitting electrical power from the array of photovoltaic cells in the electrical circuit; and each photovoltaic cell of the solar panel array is connected in the electrical circuit both in series and in parallel such that the electrical power is transmitted in the electrical circuit.

In some embodiments, the method comprises exposing the solar panel array to direct sunlight for at least 3 hours. In some specific embodiments, the method comprises exposing the solar panel array to direct sunlight for at least 6 hours. In some very specific embodiments, the method comprises exposing the solar panel array to direct sunlight for at least 9 hours.

In some embodiments, the method comprises cooling the solar panel array.

In some embodiments, the solar panel array has a temperature; and the solar panel array has an efficiency for conversion of light into electricity that inversely correlates with increased temperature.

In some embodiments, the solar panel array comprises one or more heat sinks in thermal communication with each photovoltaic cell of the array of photovoltaic cells.

In some embodiments, the one or more heat sinks cool the solar panel array.

In some embodiments, the one or more heat sinks comprise aluminum.

In some embodiments, the aluminum has sufficient surface area in thermal communication with a fluid such that the one or more heat sinks cool the solar panel array by at least 10 degrees Celsius following the 3, 6, or 9 hours of exposure of the solar panel array to direct sunlight relative to a reference solar panel array that lacks the one or more heat sinks and that is otherwise identical to the solar panel array under identical conditions of exposure to direct sunlight.

In some embodiments, the cooling improves the electricity production of the method by at least 1 percent. In some specific embodiments, the cooling improves the electricity production of the method by at least 5 percent. In some very specific embodiments, the cooling improves the electricity production of the method by at least 15 percent.

In some embodiments, the solar panel array comprises a three-dimensional shape that comprises at least two convex surfaces.

In some embodiments, each photovoltaic cell of the array of photovoltaic cells resides on a convex surface of the at least two convex surfaces.

In some embodiments, each photovoltaic cell that is configured to receive reflected light is a receiving photovoltaic cell that resides on a different convex surface relative to each photovoltaic cell that reflects light that the receiving photovoltaic cell receives, each of which photovoltaic cell(s) that reflects light is a reflecting photovoltaic cell.

In some embodiments, steps (b) and (d) comprise reflecting portions of light from reflecting photovoltaic cells to receiving photovoltaic cells.

In some embodiments, each receiving photovoltaic cell resides on a different convex surface relative to each reflecting photovoltaic cell from which the receiving photovoltaic cell receives reflected light.

In some embodiments, the array of photovoltaic cells is a passive array that lacks any automated means to orient any photovoltaic cell in relation to sunlight.

In some embodiments, the method converts the sunlight and the reflected light into electricity at a rate in kilowatt-hours of electricity per 10 megajoules of light when the array of photovoltaic cells is optimally oriented in relation to the sunlight, but passive in that the array of photovoltaic cells does not reorient in relation to the sunlight over a period of time.

In some embodiments, the photovoltaic cells of the array of photovoltaic cells have a combined total surface area that is capable of receiving light; a reference array of photovoltaic cells comprises reference photovoltaic cells that have a reference combined total surface area that is capable of receiving light; and the reference total surface area is equal to the combined total surface area.

In some embodiments, the reference photovoltaic cells of the reference array of photovoltaic cells are arranged in a plane such that each reference photovoltaic cell is oriented in the same direction, no reference photovoltaic cell is capable of reflecting any portion of light to any other reference photovoltaic cell, and the reference array of photovoltaic cells is otherwise identical to the array of photovoltaic cells.

In some embodiments, the reference photovoltaic cells of the reference array of photovoltaic cells convert light into electricity at a reference rate in kilowatt-hours of electricity per 10 megajoules of light when the reference array of photovoltaic cells is optimally oriented in relation to the sunlight, but passively oriented in that the reference array of photovoltaic cells does not reorient in relation to the sunlight over a period of time.

In some embodiments, the array of photovoltaic cells displays better efficiency than the reference array of photovoltaic cells such that the rate of conversion of light into electricity over a time period of a full day is at least 10 percent greater than the reference rate of conversion of light into electricity over the time period of the full day. In some specific embodiments, the array of photovoltaic cells displays better efficiency than the reference array of photovoltaic cells such that the rate of conversion of light into electricity over a time period of a full day is at least 40 percent greater than the reference rate of conversion of light into electricity over the time period of the full day. In some very specific embodiments, the array of photovoltaic cells displays better efficiency than the reference array of photovoltaic cells such that the rate of conversion of light into electricity over a time period of a full day is at least 80 percent greater than the reference rate of conversion of light into electricity over the time period of the full day.

In some embodiments, the first portion of the direct sunlight and the second portion of the direct sunlight have an angle of incidence, which is at least 10 degrees and no greater than 60 degrees for at least one photovoltaic cell that is configured to both receive and reflect direct sunlight as set forth in steps (a) and (b).

In some embodiments, the method lacks any automated step to orient any photovoltaic cell in relation to sunlight.

Various aspects of this disclosure relate to a solar energy system comprising a three-dimensional array of photovoltaic cells, said system designed to enhance solar production efficiency through innovative design elements. In some specific embodiments, the solar energy system comprises a three-dimensional array of photovoltaic cells, wherein (1) the system is configured to enhance solar production efficiency through innovative design elements; (2) each of the photovoltaic cells has a planar surface; (3) the system comprises a three-dimensional array of photovoltaic cells because the less than 30 percent of the planar surfaces of the photovoltaic cells are parallel to other planar surfaces of the photovoltaic cells; and (4) the system is configured to enhance solar production through innovative design elements because some of the planar surfaces of the photovoltaic cells are configured to reflect light to other planar surfaces of the photovoltaic cells.

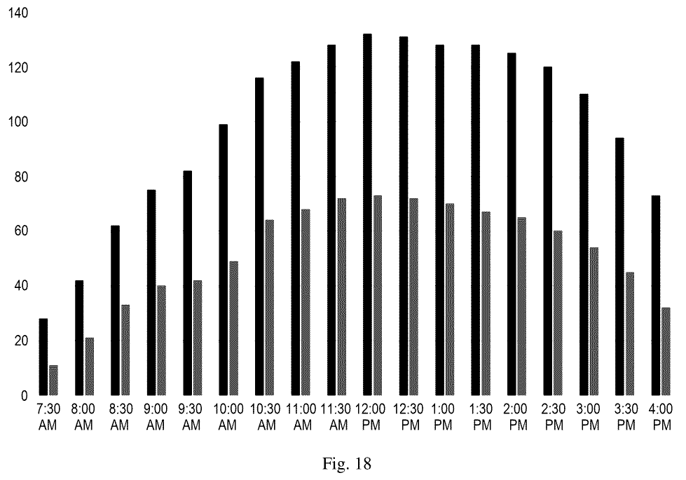

In experimental studies, a 0.25 square meter test bed was constructed to evaluate the solar production capabilities of the three-dimensional solar array design in comparison to a planar array of equivalent size. The results, as illustrated in FIG. 18, demonstrate an average 89% increase in solar production efficiency when employing the three-dimensional array. This performance improvement is attributed to the utilization of an aluminum substrate combined with optimized light redirection mechanisms inherent to the three-dimensional configuration.

In some embodiments, the three-dimensional array utilizes an aluminum substrate, further enhancing its energy production capabilities. In some specific embodiments, the system comprises an aluminum substrate in thermal communication with the photovoltaic cells, wherein: (1) the aluminum substrate is configured to remove heat from the photovoltaic cells; and (2) removing heat from the photovoltaic cells increases the solar production efficiency of the system.

The incorporation of an aluminum substrate within the three-dimensional solar array improves energy production capabilities. By leveraging the heat absorption properties of aluminum, this design maximizes solar cell heat absorption from solar cell exposure to incident light, leading to improvements in energy production.

In some embodiments, the solar energy system is capable of efficiently redirecting sunlight between solar cell rails. In some specific embodiments, the solar energy system comprises two parallel rails of photovoltaic cells, wherein: (1) the two parallel rails consist of a first rail and a second rail; (2) each rail has a convex shape, and the photovoltaic cells of a rail face outward; (3) each rail of photovoltaic cells comprises a first one or more photovoltaic cells that face a first direction and a second one or more photovoltaic cells that face a second direction; (4) the planar surfaces of the first one or more photovoltaic cells of the first rail are parallel to the planar surfaces of the first one or more photovoltaic cells of the second rail; (5) the planar surfaces of the second one or more photovoltaic cells of the first rail are parallel to the planar surfaces of the second one or more photovoltaic cells of the second rail; and (6) the system is configured such that the first photovoltaic cells of a first rail reflect light to the second photovoltaic cells of a second rail.

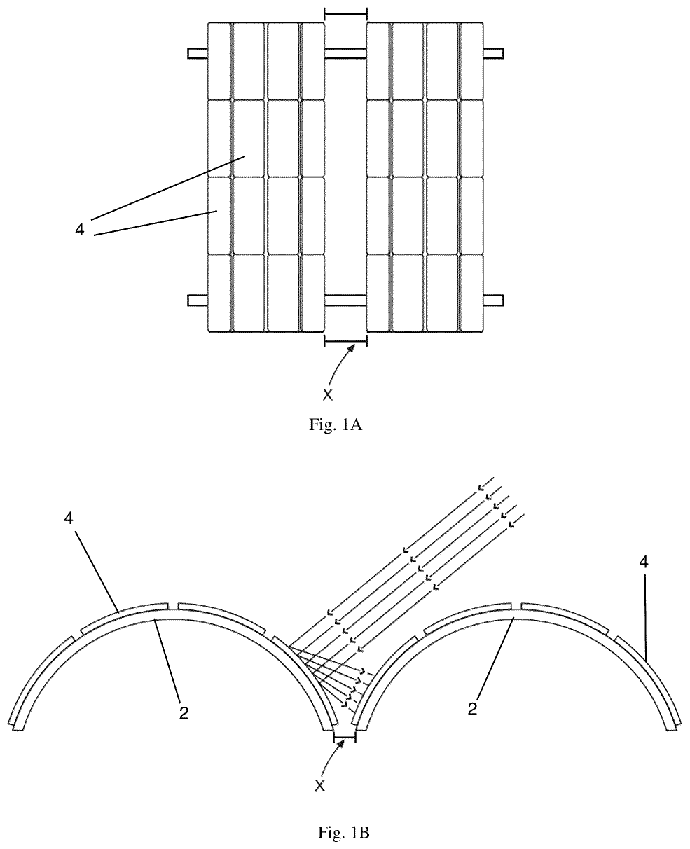

In the innovative three-dimensional array, sunlight redirection between the solar cell rails is a core feature, illustrated in FIGS. 1 and 5-7. This strategic redirection significantly contributes to the three-dimensional design's energy production enhancement, as it ensures more uniform and efficient solar cell utilization.

FIGS. 1A and 1B contain a drawing of a top view (FIG. 1A) and a side view (FIG. 1B) of an array of photovoltaic cells 4 arranged on two convex surfaces. The top view and the side view both depict a spacing “x” between the two convex surfaces. The side view depicts reflection/refraction of sunlight from one photovoltaic cell of the array to another photovoltaic cell of the array. The photovoltaic cells 4 are mounted to a supporting surface 2, which may advantageously be a thermally-conductive material such as aluminum that draws heat away from the photovoltaic cells 4.

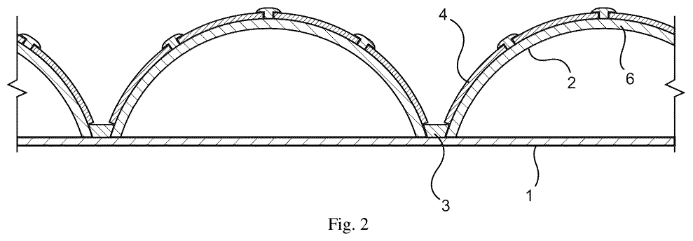

FIG. 2 is a drawing of a side view of an array of photovoltaic cells arranged on three convex surfaces. Each photovoltaic cell 4 is mounted on convex aluminum sheeting 2, which forms part of a heat sink. The drawing also depicts a base 1 and a spacer 3, which assist with ensuring the structural integrity of the array.

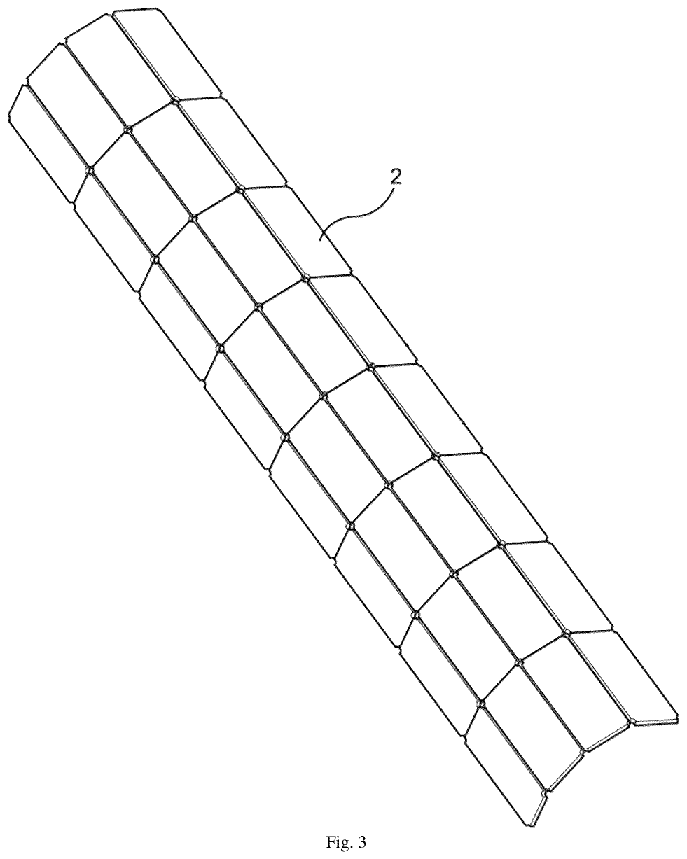

FIG. 3 is a drawing of convex aluminum sheeting 2 upon which a portion of an array of photovoltaic cells may be mounted.

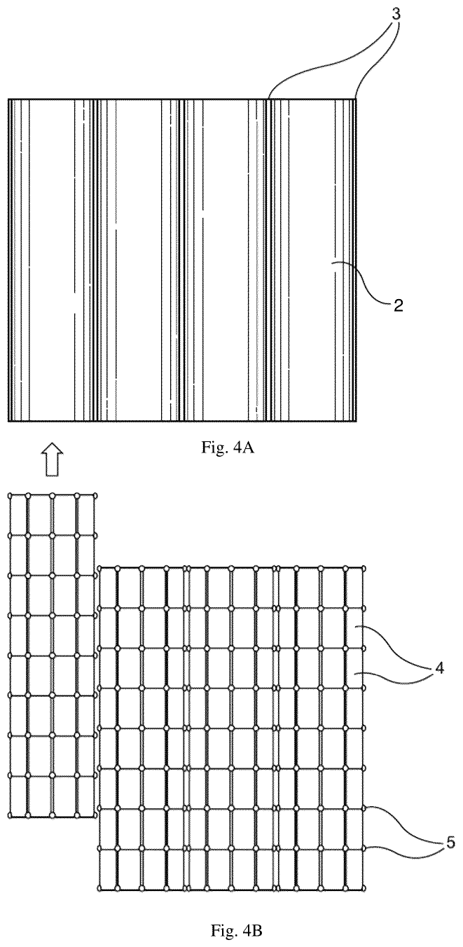

FIGS. 4A and 4B include a drawing of a top view (FIG. 4A) of convex aluminum sheeting 2 and an array of photovoltaic cells 4 (FIG. 4B) to be mounted on the convex aluminum sheeting 2 for a side-by-side configuration. The array of photovoltaic cells 4 is mounted on the convex aluminum sheeting 2 using ultraviolet-resistant fasteners 5. The convex aluminum sheeting 2 includes four convex aluminum sheets 2 according to FIG. 3.

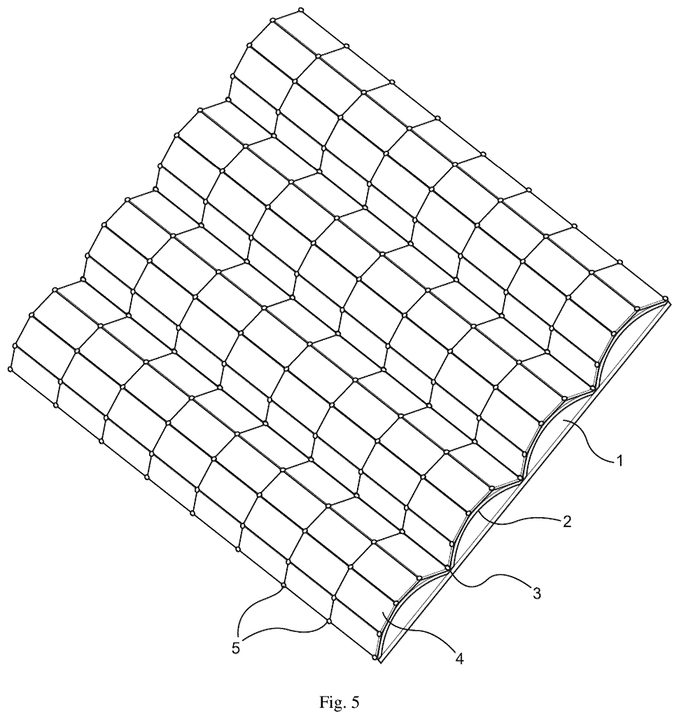

FIG. 5 is a drawing of convex aluminum sheeting 2 upon which an array of photovoltaic cells 4 has been mounted such as by mounting the array of photovoltaic cells 4 of FIG. 4B onto the convex aluminum sheeting 2 of FIG. 4A. The drawing depicts ultraviolet-resistant fasteners 5 used to mount the photovoltaic cells 4 to the convex aluminum sheeting 2 and spacers 3 between the convex aluminum sheeting 2.

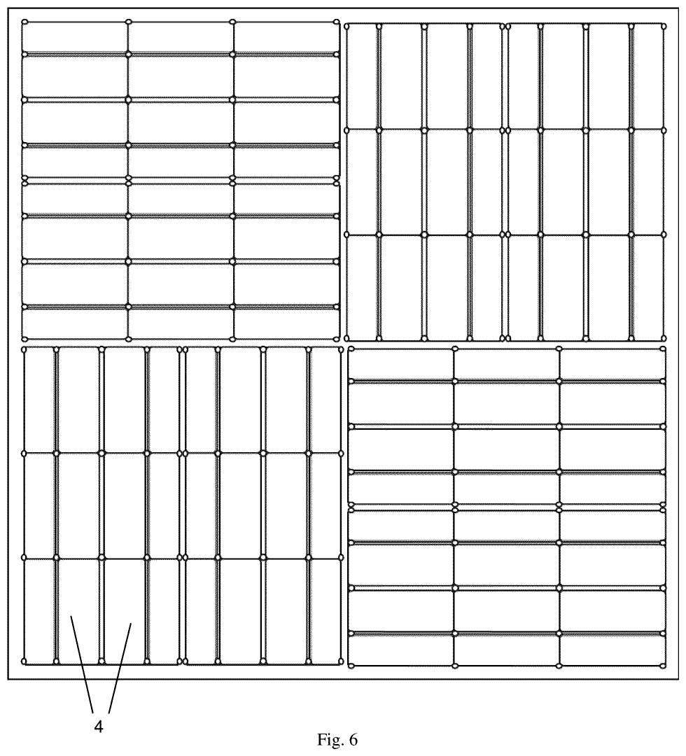

FIG. 6 is a drawing of a top view of an array of photovoltaic cells 4 mounted on aluminum sheeting with a parquet-style orientation.

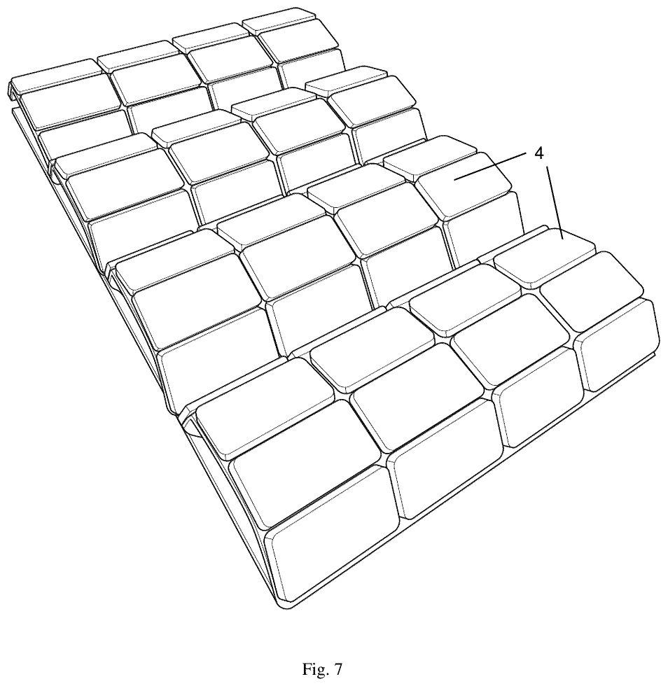

FIG. 7 is a drawing of a solar panel array, in which an array of photovoltaic cells 4 is mounted on convex aluminum sheeting in parallel rails.

FIG. 8 is a circuit diagram that depicts solar power arrays comprising photovoltaic cells (SC1, SC2, SC3, SC4, SC5, SC6, SC7, SC8, SC9, SC10, SC11, SC12, SC13, SC14, SC15, and SC16) wired in series and in parallel.

FIG. 9 is a circuit diagram of a portion of an array of photovoltaic cells wired both in series and in parallel.

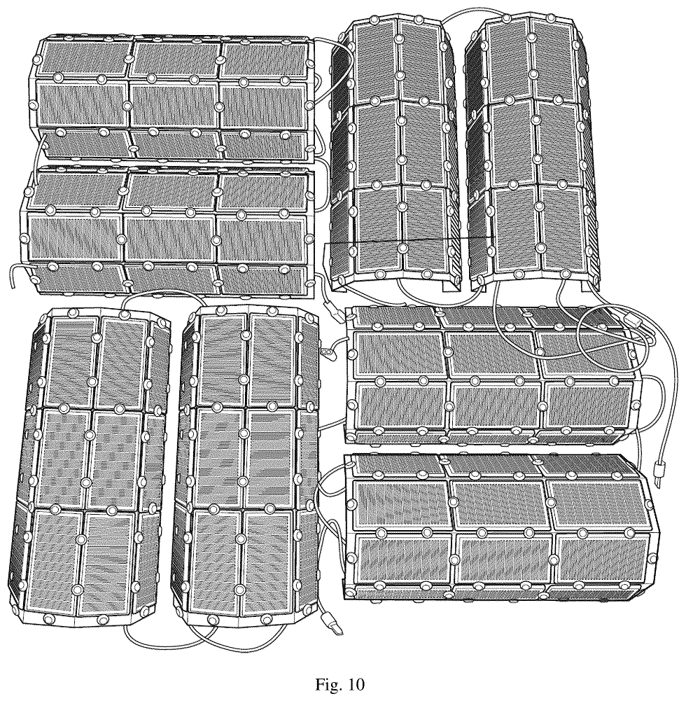

FIG. 10 depicts an array of photovoltaic cells 4 mounted on aluminum sheeting with a parquet style orientation and also depicts wiring that connects the photovoltaic cells.

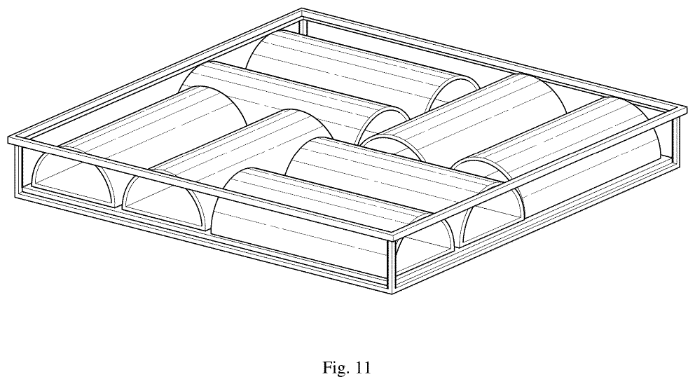

FIG. 11 depicts an array of photovoltaic cells mounted on aluminum sheeting with a parquet style orientation with a cover to protect debris from accumulating between rails of the array.

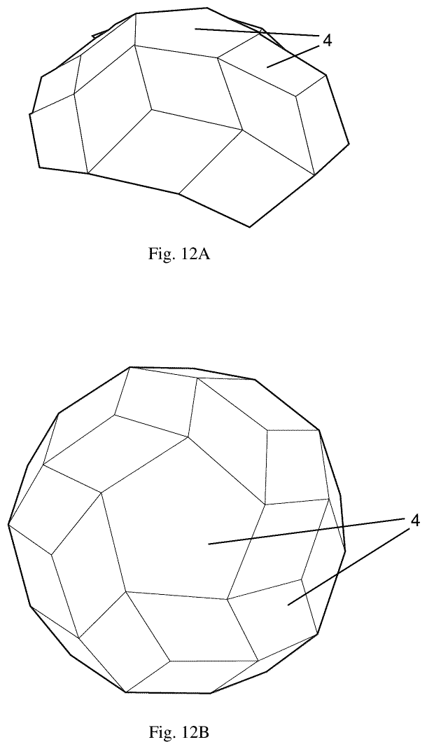

FIGS. 12A and 12B are drawings of a convex polyhedron from a perspective view (FIG. 12A) and a top view (FIG. 12B).

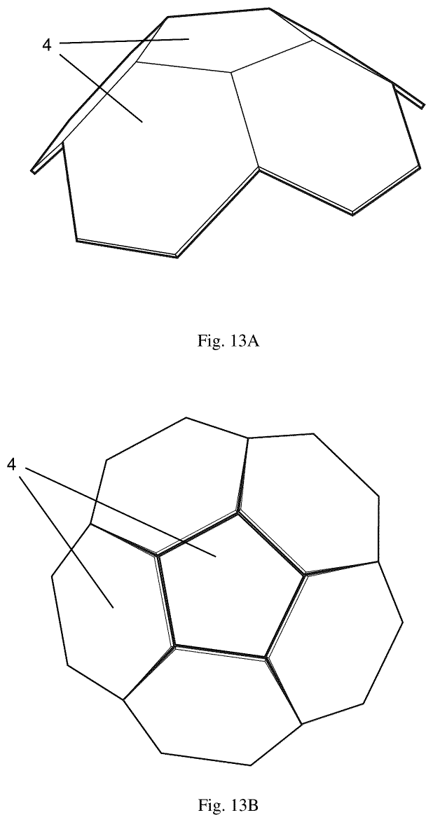

FIGS. 13A and 13B are drawings of a convex polyhedron from a perspective view (FIG. 13A) and a top view (FIG. 13B).

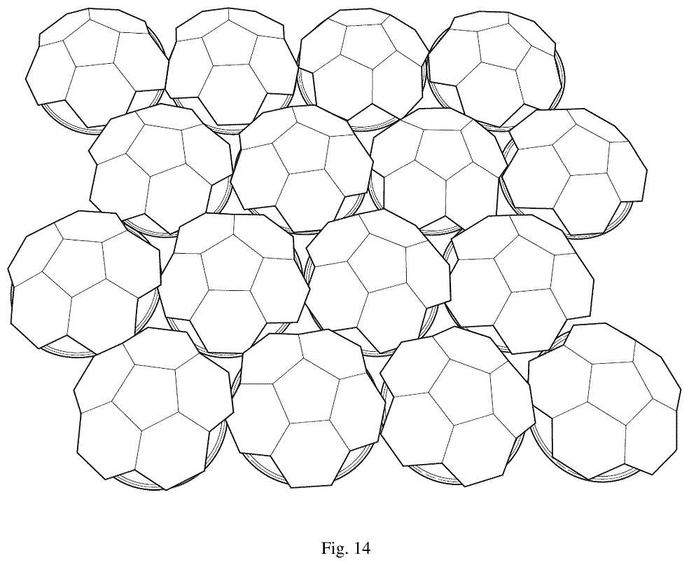

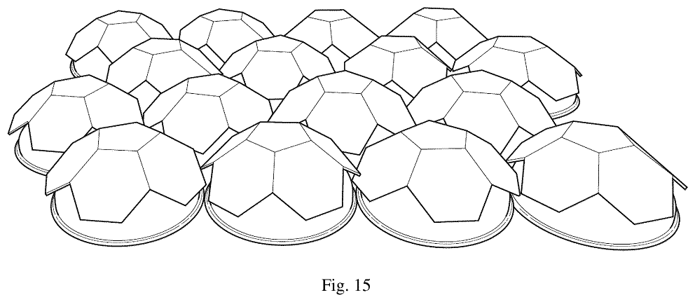

FIGS. 14 and 15 are drawings of an array of convex polyhedra from a top view (FIG. 14) and a perspective view (FIG. 15).

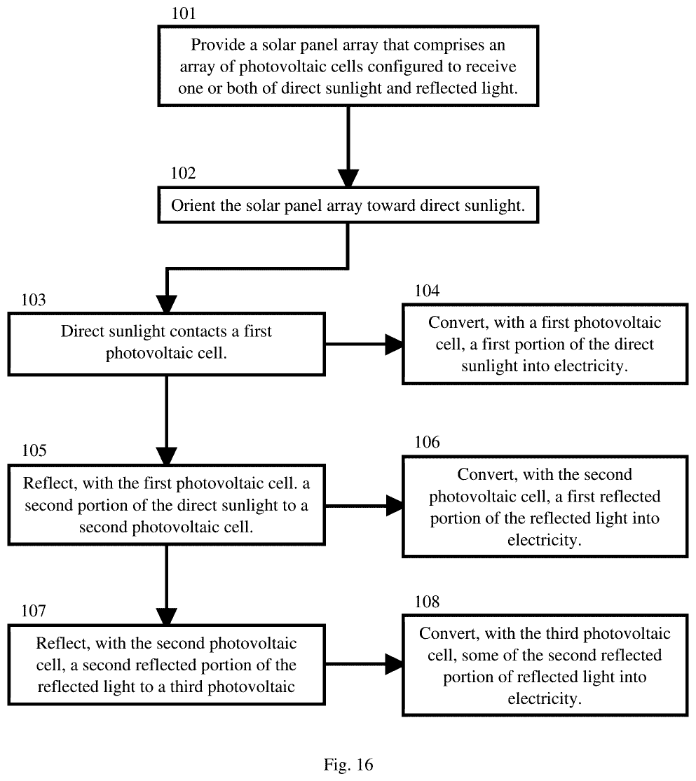

FIG. 16 is a flowchart of operations for a method of conversion of sunlight and reflected sunlight into electricity according to various embodiments of this disclosure. An operation 101 provides a solar panel array that comprises an array of photovoltaic cells configured to receive one or both of direct sunlight and reflected light. An operation 102 orients the solar panel array toward direct sunlight. An operation 103 contacts, with the direct sunlight, one or more photovoltaic cells, which converts a first portion of the direct sunlight into electricity in an operation 104 and reflects and/or refracts a second portion of the direct sunlight onto other photovoltaic cells in an operation 105. Dependent upon the orientation of the solar panel array relative to the sunlight, some photovoltaic cells that receive direct sunlight will reflect/refract sunlight away from other photovoltaic cells such that this reflected/refracted sunlight escapes the solar panel array. Solar panel arrays of this disclosure are nevertheless configured such that a significant portion of reflected/refracted sunlight is directed to other photovoltaic cells of the array.

An operation 106 converts, with the photovoltaic cells that receive reflected/refracted sunlight, a first reflected portion of the reflected/refracted light into electricity and reflect/refract a second reflected portion of the reflected light in an operation 107. Solar panel arrays of this disclosure may optionally be configured such that an operation 108 directs the second reflected portion of the reflected light to other photovoltaic cells of the array, which then convert at least some of the second reflected portion of the reflected light into electricity in an operation 108. The photovoltaic cells may advantageously be arranged in a solar panel array such that sunlight that is reflected and/or refracted by a photovoltaic cell, instead of being converted into electricity by the photovoltaic cell, is directed to one or more other photovoltaic cell(s) until the reflected/refracted light is converted into electricity or escapes the solar panel array. The inventor has unexpectedly found that such arrangements of photovoltaic cells are more efficient at converting sunlight into electricity per photovoltaic cell than conventional solar panel arrays, in which each photovoltaic cell is oriented relative to the sun for optimal conversion of direct sunlight into electricity.

FIG. 19A-19E are drawings of a rail array from different perspectives. FIG. 19A depicts and end view of a rail array and shows an ultraviolet protective epoxy resin 1, photovoltaic cells 2, a thermal paste 3, an aluminum or copper substrate 4, a wiring grid 5, a positive terminal 6, and a negative terminal 7. FIG. 19B depicts three rail arrays from an end view (textured arcs), which are stacked with packaging material between different rail arrays and covering the top rail array. FIG. 19C depicts a top view of the rail array of FIG. 19A. FIG. 19D depicts a perspective view of the rail array of FIG. 19A and FIG. 19C. FIG. 19E depicts a perspective view of a wiring diagram for the rail array of FIGS. 19A, 19C, and 19D.

In some embodiments, the solar energy system is designed to explore the use of semi-spherical aluminum substrates covered in solar cells in an efficient geometric pattern. In some specific embodiments, the solar energy system comprises two convex polyhedra, wherein: (1) the two convex polyhedral consist of a first polyhedron and a second polyhedron; (2) each polyhedron comprises at least three polygonal faces; (3) no polygonal face of a polyhedron is parallel to any other polygonal face of the same polyhedron; (4) each polyhedron is convex because each polygonal face of the polyhedron has an angle of less than 180 degrees relative to every polygonal face that is adjacent to the polygonal face as measured from within the polyhedron and an angle of greater than 180 relative to every polygonal face that is adjacent to the polygonal face as measured from outside the polyhedron; (5) a first photovoltaic cell is mounted on the first polyhedron, and a second photovoltaic cell is mounted on the second polyhedron; and (6) the system is configured such that the first photovoltaic cell can reflect light to the second photovoltaic cell.

As part of the ongoing research and future developments, an investigation in the utilization of semi-spherical aluminum substrates adorned with solar cells, arranged in an optimally efficient geometric pattern is being pursued. While specific experimental results are pending, it is anticipated that this approach, illustrated, for example, in FIGS. 14-17, will increase energy production by an additional 25 percent compared to the existing three-dimensional solar array designs.

In some embodiments, the solar energy system demonstrates a clear commitment to advancing solar technology, improving energy production, and harnessing sustainable energy sources. In some specific embodiments, the system demonstrates a clear commitment to advancing solar technology, improving energy production, and harnessing sustainable energy sources, and (1) the clear commitment is demonstrated because the system is configured to capture light that is reflected by photovoltaic cells to improve the efficiency of the system relative to systems in which reflected light is not captured; and/or (2) the clear commitment is demonstrated because the system comprises an aluminum substrate that improves the efficiency of the photovoltaic cells of the system by removing heat from the photovoltaic cells.

In some embodiments, each of the rails is adjustable and can be oriented in one of two configurations, comprising: (1) a vertical orientation, wherein the rails are adjusted so that when mounted at an angle relative to a supporting surface, the three-dimensional solar panel is in alignment with the sun's path across the sky; and (2) a parquet orientation, wherein the rails are adjusted to be substantially parallel to the supporting surface, optimizing solar energy capture regardless of the sun's angle. In some specific embodiments, the system comprises two parallel rails of photovoltaic cells, wherein: (1) the two parallel rails consist of a first rail and a second rail; (2) each rail has a convex shape, and the photovoltaic cells of a rail face outward; (3) each rail of photovoltaic cells comprises a first one or more photovoltaic cells that face a first direction and a second one or more photovoltaic cells that face a second direction; (4) the planar surfaces of the first one or more photovoltaic cells of the first rail are parallel to the planar surfaces of the first one or more photovoltaic cells of the second rail; (5) the planar surfaces of the second one or more photovoltaic cells of the first rail are parallel to the planar surfaces of the second one or more photovoltaic cells of the second rail; (6) the system is configured such that the first photovoltaic cells of a first rail reflect light to the second photovoltaic cells of a second rail; (7) the system is modular and adjustable such that the two rails may be configured in a vertical orientation, in which the two rails align with a path of the sun relative to earth; and (8) the system is modular and adjustable such that the two rails may be configured in a parquet orientation that does not align with the path of the sun relative to earth.

The solar rail system described herein may advantageously be configured as modular in design, providing flexibility in orientation. In some embodiments, each rail can be adjusted to align with the sun's path across the sky when mounted at an angle, ensuring efficient solar energy capture. In some embodiments, the solar rails can also be arranged in a parquet style, allowing the solar panel to be mounted flat on a supporting surface, thereby maximizing energy capture under varying solar angles.

In some embodiments, a UV-rated transparent impact-resistant material is securely placed atop the solar rails. This transparent material offers a flat appearance while serving the dual purpose of preventing debris or leaves from becoming lodged between the rails.

In some embodiments, 0.25 square meter solar tile is designed to lock in and connect seamlessly with adjacent solar tiles, enabling easy and secure assembly of the solar rail system.

Various aspects of this disclosure relate to a SolarSpheres solar energy capture system, which comprises a semi-spherical or convex polyhedral structure constructed, for example, from aluminum, the semi-spherical or convex polyhedral structure having a diameter, for example, of 6 to 8 inches and thereby forming a semi-spherical or convex polyhedral substrate. Each SolarSphere may be arranged in a close packing arrangement, for example, to maximize the number of SolarSpheres per unit area.

In some embodiments, a plurality of photovoltaic cells is positioned on the substrate for the conversion of solar energy into electricity.

In some embodiments, a mounting apparatus is configured to position the semi-spherical or convex polyhedral structure at an optimal angle for exposure to incident sunlight.

In some embodiments, the semi-spherical or convex polyhedral structure is characterized by a three-dimensional curvature, which maximizes the surface in a given space, thereby optimizing solar exposure.

In some embodiments, the SolarSpheres solar energy capture system provides an energy production increase of at least 80 percent over traditional flat-panel planar solar systems of equivalent surface area. In some specific embodiments, the SolarSpheres solar energy capture system provides an energy production increase of at least 100 percent over traditional flat-panel planar solar systems of equivalent surface area. In some very specific embodiments, the SolarSpheres solar energy capture system provides an energy production increase of at least 114 percent over traditional flat-panel planar solar systems of equivalent surface area.

Various aspects of this disclosure relate to a method for capturing solar energy using the SolarSpheres solar energy capture system, comprising: (1) mounting the semi-spherical or convex polyhedral structure in such a way that it maintains the optimal angle for exposure to incident sunlight; (2) directing incident sunlight onto the semi-spherical substrate; and (3) converting the incident sunlight into electricity using the photovoltaic cells positioned on the semi-spherical or convex polyhedral substrate.

Various aspects of this disclosure relate to a semi-spherical or convex polyhedral solar panel array, comprising an array of photovoltaic cells configured on a semi-spherical or convex polyhedral surface, wherein: (1) each photovoltaic cell of the array is configured to receive sunlight, including direct sunlight and optionally reflected sunlight; (2) the semi-spherical or convex polyhedral surface consists of a convex and continuous structure comprising aluminum or comparable thermally-conductive material; (3) each photovoltaic cell configured to receive direct sunlight is capable of converting a first portion of the direct sunlight into electricity; (4) at least some photovoltaic cells that are configured to receive direct sunlight are also configured to reflect a second portion of the direct sunlight towards other photovoltaic cells configured to receive reflected sunlight; (5) the angle of incidence for both the first portion of the direct sunlight and the second portion of the direct sunlight is consistent for any given photovoltaic cell that is configured to both receive and reflect direct sunlight; (6) each photovoltaic cell designed to receive reflected sunlight is constructed to convert a first reflected portion of the reflected light into electricity; (7) at least some photovoltaic cells configured to receive reflected light can also reflect a second reflected portion of the reflected light to other photovoltaic cells that are configured to receive reflected light; and (8) the semi-spherical or convex polyhedral solar panel array is designed without any automated means for orienting the photovoltaic cells in relation to sunlight.

In some embodiments, a semi-spherical or convex polyhedral solar panel array comprises a semi-spherical or convex polyhedral solar panel design comprising a 5 to 7 inch aluminum semi-sphere or convex polyhedron with photovoltaic cells arranged for optimized solar capture, wherein: (1) a keystone photovoltaic cell is positioned at an apex of the semi-sphere or convex polyhedron, parallel to a base of the semi-sphere or convex polyhedron; (2) five hexagonal photovoltaic cells are arranged at an angle of approximately 140 degrees from a normal orientation around the keystone cell; (3) the photovoltaic cells are wired both in series and in parallel; and (4) the semi-spheres or convex polyhedron are optionally arranged in an alternating pattern to maximize solar capture area.

In some embodiments, a semi-spherical or convex polyhedral solar panel array comprises a 7 to 9 inch aluminum semi-sphere or convex polyhedral solar panel design with photovoltaic cells arranged for optimized solar capture, wherein: (1) a keystone photovoltaic cell is positioned at an apex of the semi-sphere or convex polyhedron, parallel to a base of the semi-sphere or convex polyhedron; (2) fifteen diamond-shaped photovoltaic cells with two 120-degree angles and two 60-degree angles are arranged around the keystone cell, maximizing surface area for solar capture; (3) each set of three diamond-shaped photovoltaic cells combines to form a bowed hexagon pattern such that a two-dimensional projection of a set of three diamond-shaped photovoltaic cells has a hexagon shape; (4) additional modified solar diamond-shaped photovoltaic cells with one angle measuring 108 degrees are positioned between the lower edges of each hexagon to cover the entire semi-spherical area; (5) the photovoltaic cells are wired both in series and in parallel; and (6) the semi-spheres or convex polyhedron are optionally arranged in an alternating pattern to maximize solar capture area.

The embodiments of the disclosure are drafted such that various different embodiments may be combined as set forth, for example, in the multiple dependency of the claims that follow. Every combination of embodiments that is grammatically, mathematically, and logically consistent is contemplated. The skilled person may identify one or more combinations of embodiments that are unfeasible, and the existence of any such unfeasible combination shall not limit any combination of embodiments that the skilled person would identify as feasible in light of this disclosure.

The following exemplification provides a framework to utilize aspects of the invention in commercially relevant embodiments, and the exemplification does not limit the preceding disclosure, the claims that follow, or any patent claim that matures from this disclosure.

### EXEMPLIFICATION

### Example 1: Proof of Concept for Three-Dimensional Solar Arrays that Reflect Sunlight Between Different Photovoltaic Cells

A solar panel array was created by utilizing prefabricated photovoltaic cells mounted on convex aluminum sheeting with thermally-conductive compound between each photovoltaic cell and the aluminum sheeting, which was a heat sink. Ultraviolet-resistant resin was used to mount the photovoltaic cells. Each convex aluminum sheet was approximately 35.05 millimeters high, 96.52 millimeters wide, and 264.16 millimeters in length. Each photovoltaic cell was wired in electric communication with each adjacent photovoltaic cell both in series and in parallel. Multiple convex aluminum sheeting without mounted photovoltaic cells were positioned geometrically-parallel to one another with 6.35-millimeter gaps in between.

A first experimental design utilized 64 photovoltaic cells arranged on four convex aluminum sheets in a side-by-side configuration as shown in FIG. 7. A second experimental design utilized 64 photovoltaic cells arranged on four convex aluminum sheets in a parquet configuration. A control experimental design utilized 48 photovoltaic cells arranged on a planar surface, which had an identical footprint relative to 64 photovoltaic cells arranged on four convex aluminum sheets.

The solar panel arrays were oriented approximately parallel to the surface of the earth, and electricity production was recorded over an entire day. The first experimental design produced approximately 65 percent greater electricity than the control experimental design, which was surprising because the first experimental design only contained 33 percent additional surface area of photovoltaic cells than the control experimental design. The second experimental design produced approximately 74 percent greater electricity than the control experimental design, which was surprising because the first experimental design only contained 33 percent additional surface area of photovoltaic cells than the control experimental design.

The solar panel arrays were oriented at a 45-degree angle in relation to the surface of the earth, and electricity production was recorded over an entire day. The first experimental design produced approximately 56 percent greater electricity than the control experimental design, which was surprising because the first experimental design only contained 33 percent additional surface area of photovoltaic cells than the control experimental design. The second experimental design produced approximately 49 percent greater electricity than the control experimental design, which was surprising because the first experimental design only contained 33 percent additional surface area of photovoltaic cells than the control experimental design.

While a planar solar panel array likely produces greater electricity when optimal orientation relative to the sun is actively optimized in real time, the foregoing results suggest that solar panel arrays that comprise three-dimensional shapes that allow for the generation of electricity from reflected sunlight produce greater electricity when an optimal orientation relative to the sun is fixed.

### Example 2: A Prototype of a Three-Dimensional Solar Panel Array Significantly Outperforms a Conventional, Planar Array

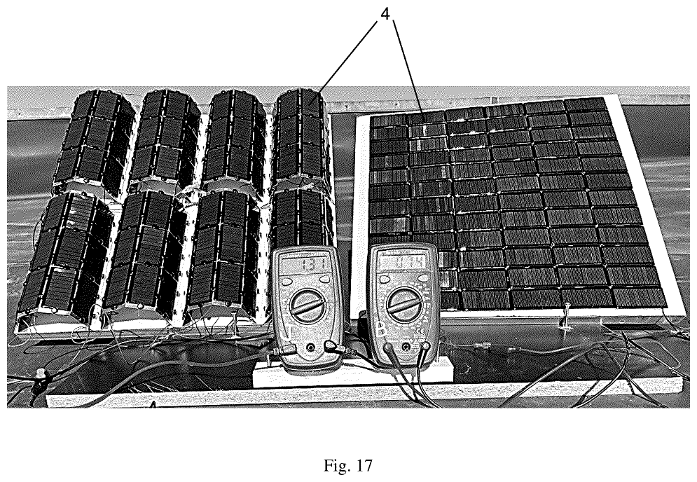

A solar panel array of this disclosure (“rail array”) was assembled comprising 72 photovoltaic cells arranged on aluminum in four rails similar to FIG. 7. A reference solar panel array (“flat array”) was assembled comprising 72 photovoltaic cells arranged on a flat aluminum surface. Both arrays had a 2-dimensional footprint of about 0.25 square meters. FIG. 17 is a photograph of the two arrays connected to two different AstroAl AM33D multimeters (AstroAl, California, United States). The multimeter connected to the rail array reads 1.31 milliamperes, and the multimeter connected to the flat array reads 0.74 milliamperes.

Both arrays were positioned facing the sun such that the flat array was approximately perpendicular to the sun at about 12 PM noon and such that the 2-dimensional footprint of the rail array was approximately parallel to the flat array. Electrical current was monitored at half-hour intervals from 7:30 AM to 4:00 PM on a clear day that lacked significant cloud coverage.

FIG. 18 depicts the electrical current generated by the rail array (black bars) and the flat array (gray bars). The y-axis of FIG. 18 depicts milliamperes. The rail array generated significantly more electrical current than the flat array at all timepoints, which was unexpected. The rail array notably generated more than 70 percent more electrical current than the flat array at any given timepoint and more than twice as much electrical current as the flat array at 7:30 AM, 3:30 PM, and 4:00 PM. These results confirm that the solar panel arrays of this disclosure are significantly more efficient than conventional solar panel arrays.

The methods described in this disclosure include examples of implementations, and the operations and the steps may be rearranged or otherwise modified such that other implementations are possible. In some examples, aspects from two or more of the methods may be combined. For example, aspects of each of the methods may include steps or aspects of the other methods, or other steps or techniques described herein. Thus, aspects of the disclosure may provide for consumer preference.

The description set forth herein describes example configurations and does not represent all the examples that may be implemented or that are within the scope of the claims. The term “exemplary” used herein means “serving as an example, instance, or illustration,” and not “preferred” or “advantageous over other examples.” The detailed description includes specific details for the purpose of providing an understanding of the described techniques. These techniques, however, may be practiced without these specific details.

The description herein is provided to enable a person skilled in the art to make or use the disclosure. Various modifications to the disclosure will be readily apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A solar panel array, comprising an array of photovoltaic cells, wherein:
each photovoltaic cell of the array of photovoltaic cells is configured to receive one or both of direct sunlight and reflected light;
the direct sunlight consists of photons emitted from the sun;
each photovoltaic cell that is configured to receive the direct sunlight is configured to convert a first portion of the direct sunlight into electricity;
at least some photovoltaic cells that are configured to receive the direct sunlight are configured to reflect a second portion of the direct sunlight to one or more other photovoltaic cells that are configured to receive reflected light;
the first portion of the direct sunlight and the second portion of the direct sunlight have an angle of incidence, the angle of incidence which is the same for any given photovoltaic cell that is configured to both receive and reflect direct sunlight;
each photovoltaic cell that is configured to receive reflected light is configured to convert a first reflected portion of the reflected light into electricity;
at least some photovoltaic cells that are configured to receive reflected light are optionally configured to reflect a second reflected portion of the reflected light to one or more other photovoltaic cells that are configured to receive reflected light;
the solar panel array optionally comprises one or more photovoltaic cells that are configured to receive the direct sunlight and convert a portion of the direct sunlight into electricity, but that are not configured to reflect a different portion of the direct sunlight to one or more other photovoltaic cells, which configuring optionally depends upon an array orientation of the solar panel array relative to the sun or a cell orientation of the one or more photovoltaic cells relative to the sun; and
conversion of the reflected light into electricity generates at least 1 kilowatt-hour of electricity per every 10 kilowatt-hours of electricity that conversion of the direct sunlight into electricity generates.

2. The solar panel array of claim 1, comprising an electrical circuit that is configured to transmit electrical power from the array of photovoltaic cells, wherein:
the electrical circuit comprises each photovoltaic cell of the array of photovoltaic cells; and
each photovoltaic cell of the array of photovoltaic cells is connected within the electrical circuit both in series and in parallel such that the electrical circuit can transmit electrical power when less than all of the photovoltaic cells of the array of photovoltaic cells are converting light into electricity.

3. The solar panel array of claim 1, comprising one or more heat sinks in thermal communication with each photovoltaic cell of the array of photovoltaic cells, wherein:
the one or more heat sinks comprise aluminum; and
the aluminum has sufficient surface area in thermal communication with a fluid such that the one or more heat sinks are capable of cooling the array of photovoltaic cells.

4. The solar panel array of claim 1, wherein:
the solar panel array comprises a three-dimensional shape that comprises at least two convex surfaces;
each photovoltaic cell of the array of photovoltaic cells resides on a convex surface of the at least two convex surfaces;
each photovoltaic cell that is configured to receive reflected light is a receiving photovoltaic cell that resides on a different convex surface relative to each photovoltaic cell that reflects light that the receiving photovoltaic cell receives; and
when a receiving photovoltaic cell receives reflected light from more than one other photovoltaic cell, then the amount of reflected light that the receiving photovoltaic cell receives from each other photovoltaic cell correlates with a distance between the receiving photovoltaic cell and each other photovoltaic cell.

5. The solar panel array of claim 1, wherein;
the photovoltaic cells of the array of photovoltaic cells have a combined total surface area that is capable of receiving light;
a reference array of photovoltaic cells comprises reference photovoltaic cells that have a reference combined total surface area that is capable of receiving light;
the reference total surface area is equal to the combined total surface area;
the array of photovoltaic cells is a passive array;
the reference photovoltaic cells of the reference array of photovoltaic cells are arranged in a plane such that each reference photovoltaic cell is oriented in the same direction, no reference photovoltaic cell is capable of reflecting any portion of light to any other reference photovoltaic cell;
the photovoltaic cells of the array of photovoltaic cells convert light into electricity at a rate when the array of photovoltaic cells is oriented in relation to the sunlight, and passively oriented in that the reference array of photovoltaic cells does not reorient in relation to the sunlight over a period of time;
the reference photovoltaic cells of the reference array of photovoltaic cells convert light into electricity when the reference array of photovoltaic cells is optimally oriented in relation to the sunlight, and passively oriented in that the reference array of photovoltaic cells does not reorient in relation to the sunlight over a period of time; and
the array of photovoltaic cells displays increased efficiency than the reference array of photovoltaic cells such that the rate of conversion of light into electricity over a time period of a full day is at least 10 percent greater than the reference rate of conversion of light into electricity over the time period of the full day.

6. The solar panel array of claim 1, wherein the first portion of direct sunlight and the first reflected portion of the reflected light each have a range of wavelengths; and
the range of wavelengths of the first portion of direct sunlight overlaps with the range of wavelengths of the first reflected portion of the reflected light.

7. The solar panel array of claim 1, wherein the solar panel array is a passive solar panel array.

8. A solar panel array, comprising a primary photovoltaic cell and a secondary photovoltaic cell, wherein:
the primary photovoltaic cell is configured to simultaneously convert a first portion of light into electricity and reflect a second portion of light;
the first portion of light and the second portion light consist of sunlight that has an identical angle of incidence relative to the primary photovoltaic cell;
the solar panel array is configured such that the second portion of light is reflected from the primary photovoltaic cell to the secondary photovoltaic cell;
the secondary photovoltaic cell is configured to receive the second portion of light and convert the second portion of light into electricity; and
the secondary photovoltaic cell is optionally configured to receive direct sunlight, to convert a portion of the direct sunlight into electricity, and to reflect another portion of the sunlight.

9. The solar panel array of claim 8, wherein the second portion of light generates at least 100 kilowatt-hours of electricity per every 1000 kilowatt-hours of electricity that the first portion of light generates.

10. The solar panel array of claim 8, wherein:
the primary photovoltaic cell is configured to refract photons;
the second portion of light comprises refracted and reflected photons that are both refracted and reflected by the primary photovoltaic cell;
the second portion of light optionally comprises reflected photons that are reflected but not refracted by the primary photovoltaic cell; and
the second portion of light comprises more refracted and reflected photons than reflected photons.

11. The solar panel array of claim 8, comprising a third photovoltaic cell, wherein:
the primary photovoltaic cell is configured to simultaneously convert the first portion of light into electricity, reflect the second portion of light, and refract a third portion of light;
the third photovoltaic cell is configured to receive the third portion of light and convert the third portion of light into electricity; and
the first portion of light, the second portion light, and the third portion of light consist of sunlight that has an identical angle of incidence relative to the primary photovoltaic cell.

12. The solar panel array of claim 11, wherein the third portion of light generates at least 1 kilowatt-hour of electricity per every 1000 kilowatt-hours of electricity that the first portion of light generates.

13. A method of generating solar power, comprising:
providing a solar panel array that comprises an array of photovoltaic cells that comprise photovoltaic cells that are configured to receive one or both of direct sunlight and reflected light; and
exposing the solar panel array to direct sunlight such that:
(a) at least some photovoltaic cells receive the direct sunlight and convert a first portion of the direct sunlight into electricity;
(b) at least some photovoltaic cells that receive the direct sunlight reflect a second portion of the direct sunlight to one or more other photovoltaic cells that are configured to receive reflected light;
(c) at least some photovoltaic cells receive the reflected light and convert a first reflected portion of the reflected light into electricity; and
(d) at least some photovoltaic cells that receive the reflected light optionally reflect a second reflected portion of the reflected light to one or more other photovoltaic cells that are configured to receive reflected light,
wherein:
the method is performed such that steps (c) and (d) are optionally repeated one or more times;
the first portion of the direct sunlight and the second portion of the direct sunlight have an angle of incidence, which is the same for any given photovoltaic cell that is configured to both receive and reflect direct sunlight; and
conversion of reflected light into electricity during step (c) generates at least 4 kilowatt-hours of electricity per every 10 kilowatt-hours of electricity that conversion of the direct sunlight into electricity during step (a) generates.

14. The method of claim 13, wherein the solar power array is a solar power array according to claim 1.

15. The method of claim 13, wherein:
exposing the solar panel array to direct sunlight comprises orienting the solar panel array such that at least one of the photovoltaic cells of the solar panel array does not convert light into electricity;
the solar panel array comprises an electrical circuit that is configured to transmit electrical power from the array of photovoltaic cells;
the method comprises transmitting electrical power from the array of photovoltaic cells in the electrical circuit; and
each photovoltaic cell of the solar panel array is connected in the electrical circuit both in series and in parallel such that the electrical power is transmitted in the electrical circuit.

16. The method of claim 13, comprising:
exposing the solar panel array to direct sunlight; and
cooling the solar panel array,
wherein:
the solar panel array has a temperature;
the solar panel array has an efficiency for conversion of light into electricity that inversely correlates with increased temperature;
the solar panel array comprises one or more heat sinks in thermal communication with each photovoltaic cell of the array of photovoltaic cells;
the one or more heat sinks cool the solar panel array;
the one or more heat sinks comprise aluminum; and
the aluminum has sufficient surface area in thermal communication with a fluid such that the one or more heat sinks cool the solar panel array following exposure of the solar panel array to direct sunlight.

17. The method of claim 13, wherein:
the solar panel array comprises a three-dimensional shape that comprises at least two convex surfaces;
each photovoltaic cell of the array of photovoltaic cells resides on a convex surface of the at least two convex surfaces;
each photovoltaic cell that is configured to receive reflected light is a receiving photovoltaic cell that resides on a different convex surface relative to each photovoltaic cell that reflects light that the receiving photovoltaic cell receives, each of which photovoltaic cell(s) that reflects light is a reflecting photovoltaic cell;
steps (b) and (d) comprise reflecting portions of light from reflecting photovoltaic cells to receiving photovoltaic cells; and
each receiving photovoltaic cell resides on a different convex surface relative to each reflecting photovoltaic cell from which the receiving photovoltaic cell receives reflected light.

18. The method of claim 13, wherein:
the array of photovoltaic cells is a passive array;
the method converts the sunlight and the reflected light into electricity when the array of photovoltaic cells is optimally oriented in relation to the sunlight, and passively oriented in that the array of photovoltaic cells does not reorient in relation to the sunlight over a period of time;
the photovoltaic cells of the array of photovoltaic cells have a combined total surface area that is capable of receiving light;
a reference array of photovoltaic cells comprises reference photovoltaic cells that have a reference combined total surface area that is capable of receiving light;
the reference total surface area is equal to the combined total surface area;
the reference photovoltaic cells of the reference array of photovoltaic cells are arranged in a plane such that each reference photovoltaic cell is oriented in the same direction, no reference photovoltaic cell is capable of reflecting any portion of light to any other reference photovoltaic cell, and the reference array of photovoltaic cells is otherwise identical to the array of photovoltaic cells;
the reference photovoltaic cells of the reference array of photovoltaic cells convert light into electricity at a reference rate in kilowatt-hours of electricity per 10 megajoules of light when the reference array of photovoltaic cells is optimally oriented in relation to the sunlight, but passively oriented in that the reference array of photovoltaic cells does not reorient in relation to the sunlight over a period of time; and
the array of photovoltaic cells displays better efficiency than the reference array of photovoltaic cells such that the rate of conversion of light into electricity over a time period of a full day is at least 10 percent greater than the reference rate of conversion of light into electricity over the time period of the full day.

19. The method of claim 13, wherein the first portion of the direct sunlight and the second portion of the direct sunlight have an angle of incidence, which is at least 10 degrees and no greater than 60 degrees for at least one photovoltaic cell that is configured to both receive and reflect direct sunlight.

20. The method of claim 13, wherein the method lacks any automated step to orient any photovoltaic cell in relation to sunlight.
